(19) United States
(12) Patent Application Publication
(10) Pub. No.: US 2025/0015042 A1
(43) Pub. Date: Jan. 9, 2025

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Jing Cheng LIN, Suwon-si (KR); Youngkun JEE, Suwon-si (KR)

(73) Assignee: SAMSUNG ELECTRONICS CO., LTD., Suwon-si (KR)

(21) Appl. No.: 18/751,869

(22) Filed: Jun. 24, 2024

(30) Foreign Application Priority Data
Jul. 5, 2023 (KR) 10-2023-0087269

(51) Int. Cl. H01L 23/00; H01L 21/56; H01L 23/498

(52) U.S. Cl. CPC H01L 24/81; H01L 21/56; H01L 24/16; H01L 24/17; H01L 24/32; H01L 24/73; H01L 23/49811; H01L 23/49833; H01L 2224/16227; H01L 2224/1703; H01L 2224/32225; H01L 2224/73204; H01L 2224/81005; H01L 2224/81047; H01L 2224/81143; H01L 2924/1815

(57) ABSTRACT

A method of manufacturing a semiconductor package is provided. The method includes: forming a plurality of sacrificial pads on a carrier substrate and a plurality of sacrificial solder bumps on the plurality of sacrificial pads, respectively; forming a plurality of conductive pillars and a protective insulating layer on a semiconductor chip, the protective insulating layer surrounding a side surface of each of the plurality of conductive pillars; polishing the plurality of conductive pillars and the protective insulating layer to obtain a polished surface in which a surface of each of the plurality of conductive pillars is coplanar with a surface of the protective insulating layer; and bonding the plurality of conductive pillars to the plurality of sacrificial solder bumps, respectively.

### CROSS-REFERENCE TO RELATED APPLICATION

This application claims priority to Korean Patent Application No. 10-2023-0087269, filed on Jul. 5, 2023, in the Korean Intellectual Property Office, the disclosure of which is incorporated by reference herein in its entirety.

### BACKGROUND

The present disclosure relates to a semiconductor package and a method of manufacturing the same, and more particularly, to a semiconductor package including a redistribution layer and a method of manufacturing the semiconductor package.

With the rapid development of the electronics industry and user needs, electronic equipment has become increasingly compact and multi-functionalized, and has an increased capacity. Accordingly, highly integrated semiconductor packages are required. Accordingly, semiconductor packages including a highly integrated semiconductor chip, which includes an increasing number of connection terminals for input/output (I/O), and having securing connection reliability have been developed.

### SUMMARY

One or more embodiments provide a method of manufacturing a semiconductor package, by which the size of the semiconductor package is reduced by decreasing a gap between a plurality of conductive pillars by self-aligning a semiconductor chip with fine-pitch pads by using the surface tension of a solder bump.

One or more embodiments also provide a method of manufacturing a semiconductor package, by which failure of the semiconductor package is reduced by suppressing a phenomenon in which a solder bump reacts to a side surface of a conductive pillar of a semiconductor chip.

Embodiments are not limited to what is mentioned above and will be clearly understood by those skilled in the art from the descriptions below.

According to an aspect of an embodiment, a method of manufacturing a semiconductor package includes: forming a plurality of sacrificial pads on a carrier substrate and a plurality of sacrificial solder bumps on the plurality of sacrificial pads, respectively; forming a plurality of conductive pillars and a protective insulating layer on a semiconductor chip, the protective insulating layer surrounding a side surface of each of the plurality of conductive pillars; polishing the plurality of conductive pillars and the protective insulating layer to obtain a polished surface in which a surface of each of the plurality of conductive pillars is coplanar with a surface of the protective insulating layer; and bonding the plurality of conductive pillars to the plurality of sacrificial solder bumps, respectively.

According to another aspect of an embodiment, a method of manufacturing a semiconductor package includes: forming a plurality of sacrificial pads on a first carrier substrate and a plurality of sacrificial solder bumps on the plurality of sacrificial pads, respectively; forming a plurality of conductive pillars and a protective insulating layer on a semiconductor chip, the protective insulating layer surrounding a side surface of each of the plurality of conductive pillars; polishing the plurality of conductive pillars and the protective insulating layer to obtain a polished surface in which a surface of each of the plurality of conductive pillars is coplanar with a surface of the protective insulating layer; bonding the plurality of conductive pillars to the plurality of sacrificial solder bumps, respectively; forming a molding layer on the first carrier substrate, the molding layer surrounding the protective insulating layer and the semiconductor chip; attaching a second carrier substrate to the semiconductor chip and removing the first carrier substrate; removing the plurality of sacrificial pads and the plurality of sacrificial solder bumps to expose the surface of each of the plurality of conductive pillars and the surface of the protective insulating layer; forming a redistribution layer on the plurality of conductive pillars and the protective insulating layer; forming an external connection terminal on the redistribution layer; and removing the second carrier substrate.

According to a further aspect of an embodiment, a method of manufacturing a semiconductor package includes: forming a plurality of sacrificial pads on a first carrier substrate and a plurality of sacrificial solder bumps on the plurality of sacrificial pads, respectively; forming a plurality of conductive pillars and a protective insulating layer on a first semiconductor chip, the protective insulating layer surrounding a side surface of each of the plurality of conductive pillars; polishing the plurality of conductive pillars and the protective insulating layer to obtain a polished surface in which a surface of each of the plurality of conductive pillars is coplanar with a surface of the protective insulating layer; bonding the plurality of conductive pillars to the plurality of sacrificial solder bumps, respectively; forming a molding layer on the first carrier substrate, the molding layer surrounding the protective insulating layer and the first semiconductor chip; attaching a second carrier substrate to the first semiconductor chip and removing the first carrier substrate; removing the plurality of sacrificial pads and the plurality of sacrificial solder bumps to expose the surface of each of the plurality of conductive pillars and the surface of the protective insulating layer; forming a first redistribution layer on the plurality of conductive pillars and the protective insulating layer; attaching a third carrier substrate to the first redistribution layer and removing the second carrier substrate; forming a plurality of connection posts that extend through the molding layer and are electrically connected to the first redistribution layer; forming a second redistribution layer on the molding layer, the plurality of connection posts, and the first semiconductor chip; arranging a second semiconductor chip on the second redistribution layer; and removing the third carrier substrate.

According to an aspect of an embodiment, a semiconductor package includes: a redistribution layer including a wiring line and a vertical via; a semiconductor chip including an active surface facing the redistribution layer; a plurality of conductive pillars between the redistribution layer and the semiconductor chip; and a protective insulating layer between the redistribution layer and the semiconductor chip, and surrounding each of the plurality of conductive pillars.

### BRIEF DESCRIPTION OF DRAWINGS

The above and other objects, features and advantages will be more apparent from the following description of embodiments, taken in conjunction with the accompanying drawings, in which:

FIG. 1 is a schematic cross-sectional view of a semiconductor package according to an embodiment;

FIG. 2 is a schematic cross-sectional view of a semiconductor package according to an embodiment;

FIG. 3 is a schematic cross-sectional view of a semiconductor package according to an embodiment;

FIG. 4 is a schematic cross-sectional view of a semiconductor package according to an embodiment;

FIG. 5 is a flowchart of a method of manufacturing a semiconductor package, according to an embodiment;

FIGS. 6 to 17 are cross-sectional views of sequential stages in a method of manufacturing a semiconductor package, according to an embodiment;

FIG. 18 is a flowchart of a method of manufacturing a semiconductor package, according to an embodiment; and

FIGS. 19 to 23 are cross-sectional views of some sequential stages in a method of manufacturing a semiconductor package, according to an embodiment.

### DETAILED DESCRIPTION

Hereinafter, embodiments will be described with reference to the accompanying drawings. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

Herein, a top surface/an upper portion and a bottom surface/a lower portion may be used differently according to directions shown in the drawings. For example, a top surface/an upper portion in a drawing (in which a vertical arrow points up) may be referred to as a bottom surface/a lower portion in another drawing (in which a vertical arrow points down). It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation. The same reference numerals are used for the same components in the drawings, and redundant descriptions thereof are omitted.

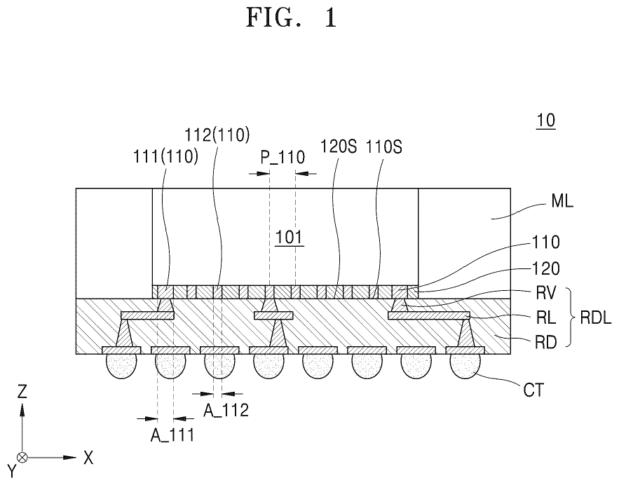

FIG. 1 is a schematic cross-sectional view of a semiconductor package 10 according to an embodiment.

Referring to FIG. 1, the semiconductor package 10 may include a first semiconductor chip 101, a plurality of conductive pillars 110, a protective insulating layer 120, a redistribution layer RDL, and a molding layer ML.

Hereinafter, unless particularly defined, a first horizontal direction (the X direction) indicates a direction parallel with the top surface of the first semiconductor chip 101, a vertical direction (the Z direction) indicates a direction perpendicular to the top surface of the first semiconductor chip 101, and a second horizontal direction (the Y direction) indicates a direction perpendicular to the first horizontal direction (the X direction) and the vertical direction (the Z direction).

The first semiconductor chip 101 of the semiconductor package 10 may include an active surface and an inactive surface opposite to the active surface. In some embodiments, the first semiconductor chip 101 may be arranged on the redistribution layer RDL such that the active surface of the first semiconductor chip 101 faces the redistribution layer RDL.

For example, the first semiconductor chip 101 may include silicon (Si). In another embodiment, the first semiconductor chip 101 may include a semiconductor element, e.g., germanium (Ge), or a compound semiconductor, such as silicon carbide (SiC), gallium arsenide (GaAs), indium arsenide (InAs), or indium phosphide (InP).

The first semiconductor chip 101 may include a conductive region, e.g., an impurity-doped well or an impurity-doped structure. A semiconductor device layer including one or more individual devices may be on the active surface of the first semiconductor chip 101. For example, the individual devices may include one or more transistors. The individual devices may include microelectronic devices, e.g., a metal-oxide-semiconductor field effect transistor (MOSFET), a system large scale integration (LSI), an image sensor such as a complementary metal-oxide-semiconductor (CMOS) image sensor (CIS), a micro-electro-mechanical system (MEMS), an active element, and a passive element.

The first semiconductor chip 101 may correspond to a memory chip or a logic chip. The memory chip may correspond to a volatile memory semiconductor device including dynamic random access memory (DRAM) or static RAM (SRAM) or a non-volatile memory semiconductor device including phase-change RAM (PRAM), magnetoresistive RAM (MRAM), ferroelectric RAM (FeRAM), or resistive RAM (RRAM). The logic chip may include a central processing unit (CPU) chip, a graphics processing unit (GPU) chip, an application processor (AP) chip, or an application specific integrated circuit (ASIC) chip.

Although it is illustrated in FIG. 1 that one first semiconductor chip 101 is mounted on the redistribution layer RDL, the number of first semiconductor chips 101 is not limited to one and at least two first semiconductor chips 101 may be mounted on the redistribution layer RDL. When at least two first semiconductor chips 101 are mounted on the redistribution layer RDL, the first semiconductor chips 101 may be of different types.

The conductive pillars 110 of the semiconductor package 10 may be on the active surface of the first semiconductor chip 101. The protective insulating layer 120 of the semiconductor package 10 may surround the side surfaces of the conductive pillars 110. In some embodiments, the length of each of the conductive pillars 110 in the vertical direction (the Z direction) may be substantially the same as the length of the protective insulating layer 120 in the vertical direction (the Z direction). For example, a surface 110S of each of the conductive pillars 110 may be coplanar with a surface 120S of the protective insulating layer 120. The surface 110S of each of the conductive pillars 110 and the surface 120S of the protective insulating layer 120 may be in contact with the redistribution layer RDL.

Hereinafter, the surface 110S of each of the conductive pillars 110 is opposite to a surface of each conductive pillar 110 which is in contact with the active surface of the first semiconductor chip 101. The surface 120S of the protective insulating layer 120 is opposite to a surface of the protective insulating layer 120 which is in contact with the active surface of the first semiconductor chip 101. For example, when the active surface of the first semiconductor chip 101 faces downwards in the vertical direction (the Z direction), each of the surface 110S of the conductive pillar 110 and the surface 120S of the protective insulating layer 120 may be referred to as the bottom surface of the conductive pillar 110 or the protective insulating layer 120. When the active surface of the first semiconductor chip 101 faces upwards in the vertical direction (the Z direction), each of the surface 110S of the conductive pillar 110 and the surface 120S of the protective insulating layer 120 may be referred to as the top surface of the conductive pillar 110 or the protective insulating layer 120.

In some embodiments, the conductive pillars 110 may be in direct contact with and electrically connected to the redistribution layer RDL, and the protective insulating layer 120 may be in direct contact with the redistribution layer RDL. In some embodiments, a distance P_110 between the respective centers of adjacent conductive pillars 110 may be about 20 μm to about 100 μm.

In some embodiments, the conductive pillars 110 may include a first conductive pillar 111 and a second conductive pillar 112, which respectively have different horizontal areas. A horizontal area A_111 of the first conductive pillar 111 may be larger than a horizontal area A_112 of the second conductive pillar 112. For example, the horizontal area A_111 of the first conductive pillar 111 may be about 120% to about 200% of the horizontal area A_112 of the second conductive pillar 112.

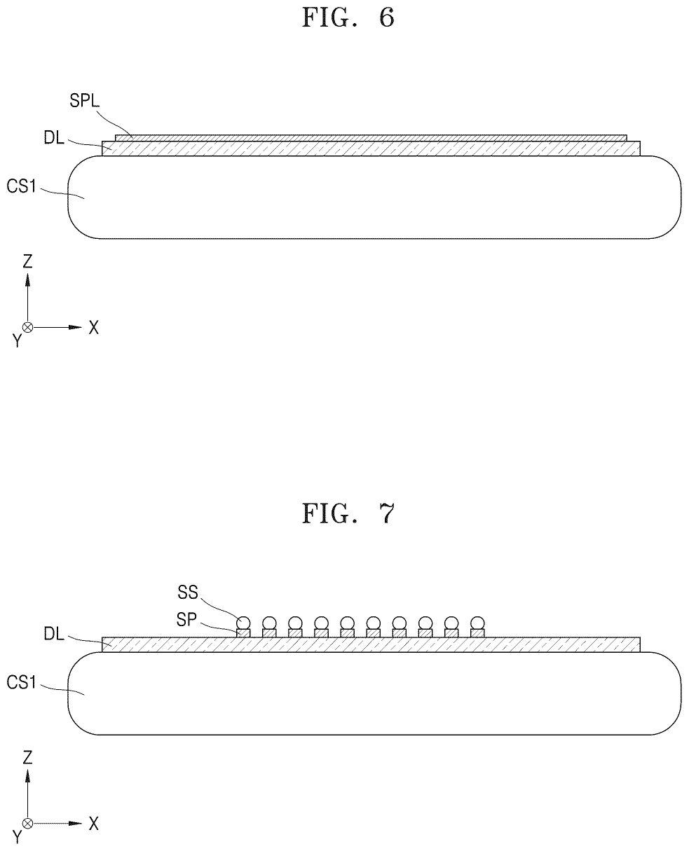

In a process of aligning the first semiconductor chip 101 with a first carrier substrate CS1 (see FIG. 6), the movement of the first semiconductor chip 101 may be effectively suppressed because the first conductive pillar 111 has a larger contact area with a sacrificial solder bump SS (see FIG. 7) than the second conductive pillar 112. Accordingly, self-alignment between the conductive pillars 110 and a plurality of sacrificial pads SP (see FIG. 7) may be easily performed.

A plurality of conductive pillars 110 on the active surface of the first semiconductor chip 101 may be respectively connected to external connection terminals CT through the redistribution layer RDL. The first semiconductor chip 101 may be connected to the external connection terminals CT through the conductive pillars 110 and the redistribution layer RDL.

In some embodiments, the conductive pillars 110 may include, but are not limited to, metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof.

The redistribution layer RDL of the semiconductor package 10 may be on the conductive pillars 110 and the protective insulating layer 120. The redistribution layer RDL may include a wiring line RL, a vertical via RV vertically connected to the wiring line RL, and an insulating layer RD surrounding the wiring line RL and the vertical via RV.

In some embodiments, the vertical via RV in the redistribution layer RDL may be structured such that the width of the vertical via RV in the first horizontal direction (the X direction) and/or the width of the vertical via RV in the second horizontal direction (the Y direction) decreases toward the bottom surface of the first semiconductor chip 101. In this regard, the horizontal area of the vertical via RV of the redistribution layer RDL may decrease toward the first semiconductor chip 101.

The molding layer ML may be on the redistribution layer RDL and may surround the first semiconductor chip 101 and the protective insulating layer 120. In some embodiments, the molding layer ML may include epoxy resin or polyimide resin. For example, the molding layer ML may include an epoxy molding compound (EMC). The molding layer ML and the protective insulating layer 120 may respectively include different materials.

A horizontal width of the molding layer ML may be substantially the same as a horizontal width of the redistribution layer RDL. For example, a side surface of the molding layer ML may be substantially coplanar with a side surface of the redistribution layer RDL. In some embodiments, the top surface of the first semiconductor chip 101 may be exposed through the molding layer ML.

An external connection terminal CT may be on the bottom surface of the redistribution layer RDL. For example, the external connection terminal CT may include a solder ball, a conductive bump, conductive paste, a ball grid array (BGA), a lead grid array (LGA), a pin grid array (PGA), or a combination thereof.

In the case of related semiconductor packages, when a semiconductor chip becomes compact or when the number of signals terminals for input/output (I/O) increases, it is difficult to accommodate all the signal terminals on the active surface of the semiconductor chip. Accordingly, the redistribution layer RDL may extend to the outside of the active surface of the first semiconductor chip to expand an area in which signal terminals are arranged. In this regard, the structure of a fan-out wafer-level package (FO-WLP) or a fan-out panel-level package (FO-PLP), which may be collectively referred to as an FO-WLP, is applied to related semiconductor packages.

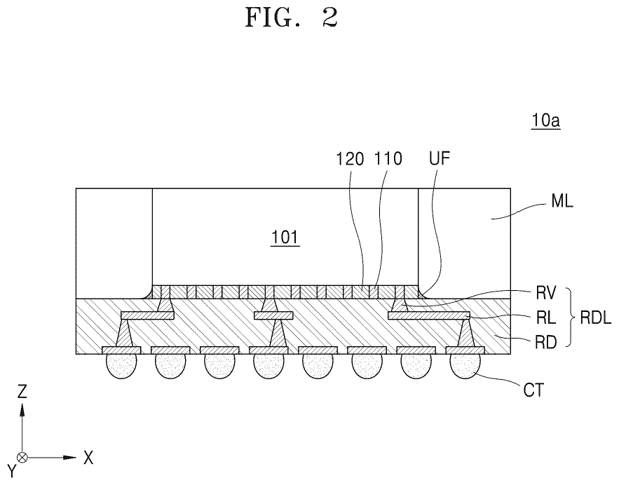

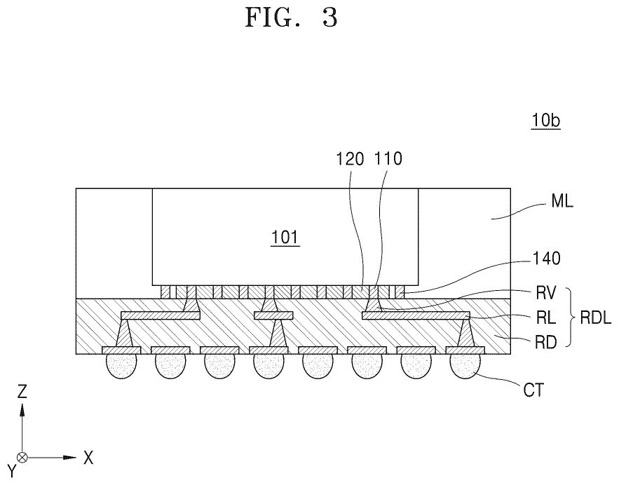

FIG. 2 is a schematic cross-sectional view of a semiconductor package 10a according to an embodiment. FIG. 3 is a schematic cross-sectional view of a semiconductor package 10b according to an embodiment.

The elements of the semiconductor packages 10a and 10b and the materials of the elements described below are mostly and substantially the same as or similar to those described above with reference to FIG. 1. Accordingly, for convenience of description, differences from the semiconductor package 10 are mainly described below.

Referring to FIG. 2, the semiconductor package 10a may further include an underfill layer UF.

The underfill layer UF of the semiconductor package 10a may surround at least a portion of the side surface of the protective insulating layer 120. In some embodiments, the underfill layer UF may completely surround the side surface of the protective insulating layer 120. The molding layer ML may surround the underfill layer UF, a portion of the side surface of the protective insulating layer 120, which is not covered with the underfill layer UF, and the first semiconductor chip 101. The horizontal width of the underfill layer UF may increase toward the redistribution layer RDL. However, the shape of the underfill layer UF is not limited thereto.

Referring to FIG. 3, the semiconductor package 10b may further include a plurality of dummy pillars 140.

The dummy pillars 140 of the semiconductor package 10b may be on the first semiconductor chip 101. The dummy pillars 140 may be on the active surface of the first semiconductor chip 101 and may be apart from the conductive pillars 110 in the first horizontal direction (the X direction) and the second horizontal direction (the Y direction).

In some embodiments, the dummy pillars 140 may be arranged to surround the conductive pillars 110. In this regard, the dummy pillars 140 may be located near the edge of the active surface of the first semiconductor chip 101 and the conductive pillars 110 may be located in the central portion of the active surface of the first semiconductor chip 101. However, the location of the dummy pillars 140 is not limited thereto. The dummy pillars 140 may be located between the conductive pillars 110.

The protective insulating layer 120 may not surround the side surfaces of the dummy pillars 140. In this regard, the side surfaces of the dummy pillars 140 may be surrounded by the molding layer ML. The dummy pillars 140 may not be electrically connected to the first semiconductor chip 101 and the redistribution layer RDL. In some embodiments, a plurality of sacrificial solder bumps SS (see FIG. 7) may overflow and may thus be on the side surfaces of the dummy pillars 140. In this regard, the overflow may effectively increase a contact area between the dummy pillars 140 and the sacrificial solder bumps SS.

In a process of aligning the first semiconductor chip 101 with the first carrier substrate CS1 (see FIG. 6), the movement of the first semiconductor chip 101 may be effectively suppressed because the dummy pillars 140 have a larger contact area with the sacrificial solder bumps SS (see FIG. 7) than the conductive pillars 110. Accordingly, self-alignment between the conductive pillars 110 and the sacrificial pads SP (see FIG. 7) may be easily performed.

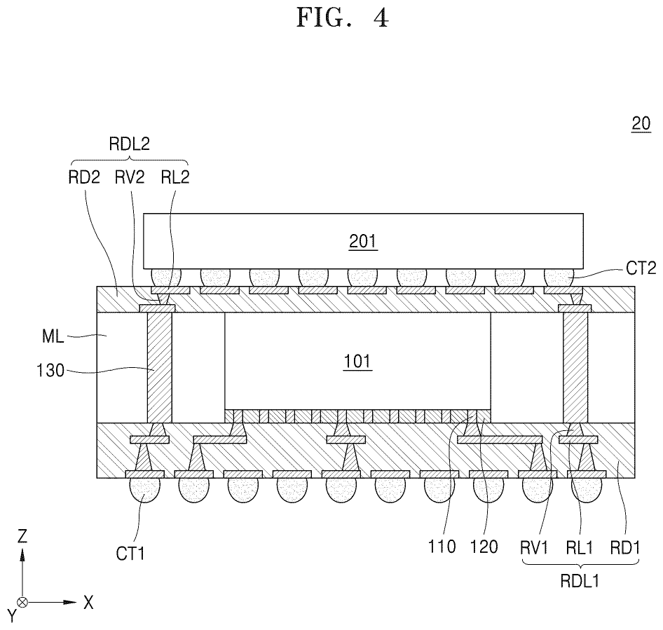

FIG. 4 is a schematic cross-sectional view of a semiconductor package 20 according to an embodiment.

Referring to FIG. 4, the semiconductor package 20 may include a first redistribution layer RDL1, the first semiconductor chip 101, the conductive pillars 110, the protective insulating layer 120, a plurality of connection posts 130, a second redistribution layer RDL2, and a second semiconductor chip 201. In some embodiments, an interposer may be provided instead of the second redistribution layer RDL2.

The elements of the semiconductor package 20 and the materials of the elements described below are mostly and substantially the same as or similar to those described above with reference to FIG. 1. Accordingly, for convenience of description, differences from the semiconductor package 10 of FIG. 1 are mainly described below.

The first redistribution layer RDL1 of the semiconductor package 20 of FIG. 4 may correspond to the redistribution layer RDL in FIG. 1, and a first wiring line RL1, a first vertical via RV1, and a first insulating layer RD1 may respectively correspond to the wiring line RL, the vertical via RV, and the insulating layer RD in FIG. 2. An external connection terminal CT1 may correspond to the external connection terminal CT described above.

The connection posts 130 of the semiconductor package 20 may be around the first semiconductor chip 101 and may pass through the molding layer ML to be electrically connected to the first redistribution layer RDL1. The connection posts 130 may pass through the molding layer ML and electrically connect the first redistribution layer RDL1 to the second redistribution layer RDL2. The molding layer ML may surround the connection posts 130. The connection posts 130 may surround the first semiconductor chip 101.

The second redistribution layer RDL2 of the semiconductor package 20 may be on the molding layer ML, the connection posts 130, and the first semiconductor chip 101.

The second redistribution layer RDL2 may include a second wiring line RL2, a second vertical via RV2 vertically connected to the second wiring line RL2, and a second insulating layer RD2 surrounding the second wiring line RL2 and the second vertical via RV2. The second vertical via RV2 in the second redistribution layer RDL2 may be structured such that the width of the second vertical via RV2 in the first horizontal direction (the X direction) and/or the width of the second vertical via RV2 in the second horizontal direction (the Y direction) decreases toward the top surface of the first semiconductor chip 101. For example, the horizontal area of the second vertical via RV2 of the second redistribution layer RDL2 may decrease toward the first semiconductor chip 101.

The second semiconductor chip 201 of the semiconductor package 20 may be on the second redistribution layer RDL2. The second semiconductor chip 201 may include an active surface and an inactive surface opposite to the active surface.

For example, the second semiconductor chip 201 may include Si. Alternatively, the second semiconductor chip 201 may include a semiconductor element, e.g., Ge, or a compound semiconductor, such as SiC, GaAs, InAs, or InP.

The second semiconductor chip 201 may include a conductive region, e.g., an impurity-doped well or an impurity-doped structure. A semiconductor device layer including individual devices may be on the active surface of the second semiconductor chip 201. For example, the individual devices may include one or more transistors. The individual devices may include microelectronic devices, e.g., a MOSFET, a system LSI, an image sensor such as a CIS, an MEMS, an active element, and a passive element.

The second semiconductor chip 201 may correspond to a memory chip or a logic chip. The memory chip may correspond to a volatile memory semiconductor device including DRAM or SRAM or a non-volatile memory semiconductor device including PRAM, MRAM, FeRAM, or RRAM. The logic chip may include a CPU chip, a GPU chip, an AP chip, or an ASIC chip.

In some embodiments, the first semiconductor chip 101 may correspond to a memory chip and the second semiconductor chip 201 may correspond to a logic chip including a logic element (e.g., a logic circuit). For example, as a memory chip, the first semiconductor chip 101 may be constituted of a volatile memory chip and/or a non-volatile memory chip. As a logic chip, the second semiconductor chip 201 may be configured as a CPU chip, a GPU chip, or an AP chip. In this regard, the second semiconductor chip 201 may perform different functions than the first semiconductor chip 101.

In some embodiments, the second semiconductor chip 201 may be arranged on the second redistribution layer RDL2 such that the active surface of the second semiconductor chip 201 faces the second redistribution layer RDL2. At this time, the second semiconductor chip 201 may be electrically connected to the second redistribution layer RDL2 through an internal connection terminal CT2 between the second semiconductor chip 201 and the second redistribution layer RDL2. In this regard, the second semiconductor chip 201 may be electrically connected to the first redistribution layer RDL1 through the internal connection terminal CT2, the second redistribution layer RDL2, and the connection posts 130.

In some embodiments, the second semiconductor chip 201 may be arranged on the second redistribution layer RDL2 such that the inactive surface of the second semiconductor chip 201 faces the second redistribution layer RDL2. The second semiconductor chip 201 may be electrically connected to the second redistribution layer RDL2 through a conductive wire.

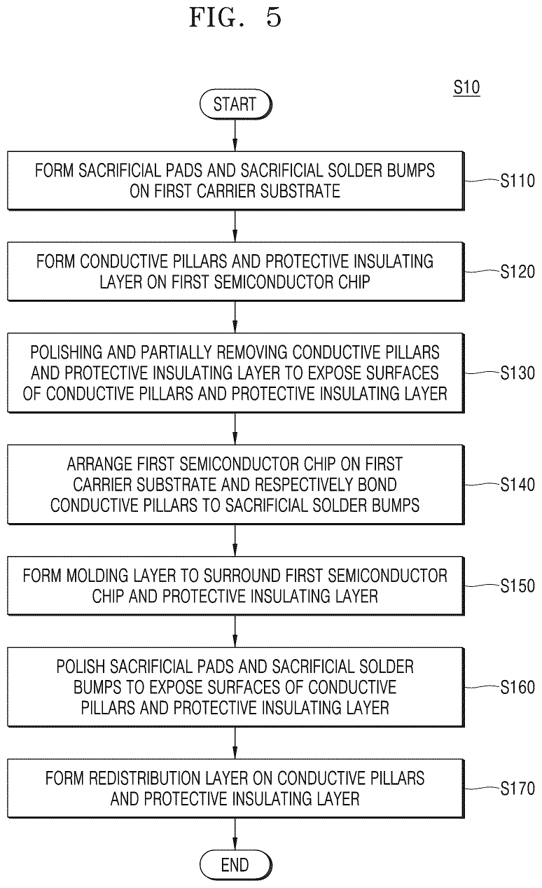

FIG. 5 is a flowchart of a method S10 of manufacturing a semiconductor package, according to an embodiment.

Referring to FIG. 5, the method S10 of manufacturing a semiconductor package may include forming a plurality of sacrificial pads and a plurality of sacrificial solder bumps on a first carrier substrate in operation S110, forming a plurality of conductive pillars and a protective insulating layer on a first semiconductor chip in operation S120, polishing and partially removing the conductive pillars and the protective insulating layer to expose the surfaces of the conductive pillars and the surface of the protective insulating layer in operation S130, arranging the first semiconductor chip on the first carrier substrate and respectively bonding the conductive pillars to the sacrificial solder bumps in operation S140, forming a molding layer to surround the first semiconductor chip and the protective insulating layer in operation S150, polishing the sacrificial pads and the sacrificial solder bumps to expose the surfaces of the conductive pillars and the surface of the protective insulating layer in operation S160, and forming a redistribution layer on the conductive pillar and the protective insulating layer in operation S170.

In another embodiment, the order of operations may be different from the order in which the operations are described. For example, two operations described as being performed sequentially may be substantially performed simultaneously or in a reverse order.

The method S10 of manufacturing a semiconductor package is described in detail with reference to FIGS. 6 to 17 below.

FIGS. 6 to 17 are cross-sectional views of sequential stages in a method of manufacturing a semiconductor package, according to an embodiment.

Referring to FIG. 6, an adhesive insulating layer DL may be attached to a first carrier substrate CS1 and a sacrificial pad layer SPL may be formed on the adhesive insulating layer DL.

For example, the first carrier substrate CS1 may include glass, silicon, or aluminum oxide. The adhesive insulating layer DL may include a material capable of fixing the sacrificial pad layer SPL to the first carrier substrate CS1. For example, the adhesive insulating layer DL may include adhesive tape, the adhesive strength of which may be weakened by heat treatment or laser irradiation. The sacrificial pad layer SPL may correspond to a conductive layer including copper (Cu).

Referring to FIG. 7, a plurality of sacrificial pads SP may be formed by patterning the sacrificial pad layer SPL (see FIG. 6) by using a photolithography process and an etching process.

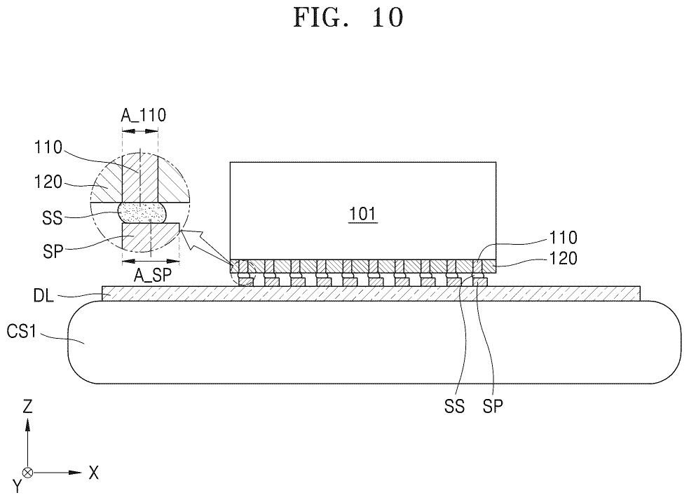

The sacrificial pads SP may be formed to have a fine pitch therebetween. For example, the sacrificial pads SP may be formed to have a pitch of about 20 micrometers to about 100 micrometers, but embodiments are not limited thereto. The sacrificial pads SP may be formed in a region on which a first semiconductor chip 101 (see FIG. 10) is to be mounted.

A plurality of sacrificial solder bumps SS may be respectively formed on the sacrificial pads SP. The sacrificial solder bumps SS may include leaded solder, including tin (Sn) and lead (Pb), or unleaded solder including Sn but not Pb.

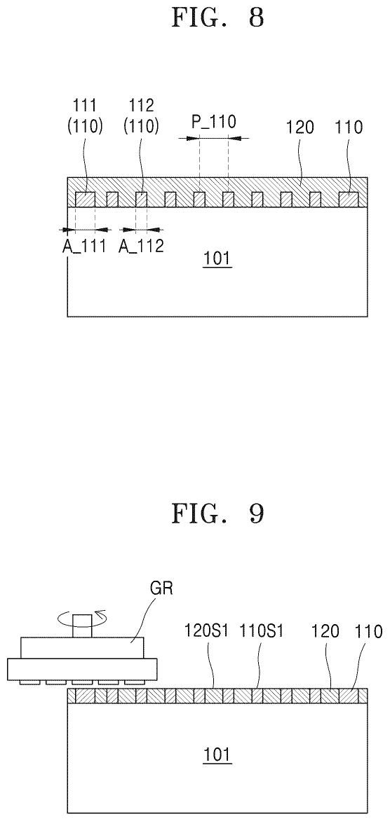

Referring to FIG. 8, a plurality of conductive pillars 110 and a protective insulating layer 120 may be formed on the first semiconductor chip 101.

The conductive pillars 110 may be formed to be electrically connected to the active surface of the first semiconductor chip 101 and the protective insulating layer 120 may be formed to entirely surround the conductive pillars 110 and cover the conductive pillars 110. In some embodiments, a distance P_110 between the respective centers of adjacent conductive pillars 110 may be about 20 μm to about 100 μm.

In some embodiments, the conductive pillars 110 may include a first conductive pillar 111 and a second conductive pillar 112, which respectively have different horizontal areas. A horizontal area A_111 of the first conductive pillar 111 may be larger than a horizontal area A_112 of the second conductive pillar 112. The horizontal area A_111 of the first conductive pillar 111 may be about 1.2 to about 2 times the horizontal area A_112 of the second conductive pillar 112.

In some embodiments, the conductive pillars 110 may include, but are not limited to, metal, such as Cu, Al, W, Ti, Ta, In, Mo, Mn, Co, Sn, Ni, Mg, Re, Be, Ga, or Ru, or an alloy thereof. The protective insulating layer 120 may include, but is not limited to, photo-imageable dielectric (PID), photosensitive polyimide (PSPI), SiO₂, SiCN, or SiN.

In some embodiments, after the conductive pillars 110 are formed on the first semiconductor chip 101, the protective insulating layer 120 may be formed to surround the conductive pillars 110. At this time, the protective insulating layer 120 may cover the top surfaces of the conductive pillars 110.

In some embodiments, after the protective insulating layer 120 is formed on the first semiconductor chip 101, a plurality of through holes may be formed in the protective insulating layer 120 by patterning the protective insulating layer 120 by using a photolithography process and an etching process. A plurality of conductive pillars respectively filling the through holes may be formed by a deposition or plating process. At this time, the protective insulating layer 120 may not cover the top surfaces of the conductive pillars 110.

Referring to FIG. 9, the conductive pillars 110 and the protective insulating layer 120 may be partially removed such that a surface 110S1 of each of the conductive pillars 110 is coplanar with a surface 120S1 of the protective insulating layer 120.

Polishing and planarization may be performed on the conductive pillars 110 and the protective insulating layer 120 by using a grinder GR. The polishing and planarization may include chemical mechanical polishing (CMP). The grinder GR may partially remove the protective insulating layer 120 and the conductive pillars 110 so that the surface 110S1 of each of the conductive pillars 110 and the surface 120S1 of the protective insulating layer 120 form a flat surface. In this regard, the surface 110S1 of each of the conductive pillars 110 may be coplanar with the surface 120S1 of the protective insulating layer 120.

In some embodiments, when the protective insulating layer 120 covers the top surfaces of the conductive pillars 110, a portion of the protective insulating layer 120 above the conductive pillars 110 may be polished and removed.

Referring to FIG. 10, the first semiconductor chip 101 of FIG. 9 may be disposed on the sacrificial solder bumps SS of the first carrier substrate CS1 shown in FIG. 7.

The conductive pillars 110 of the first semiconductor chip 101 may contact the sacrificial solder bumps SS, respectively. In this case, as shown in FIG. 10, the central axis of each of the conductive pillars 110 may not be aligned with the central axis of its corresponding one among the sacrificial pads SP with its corresponding one of the sacrificial solder bumps SS therebetween. This may be caused by an error occurring during alignment of micropatterns.

In some embodiments, a horizontal area A_110 of each of the conductive pillars 110 may be different from a horizontal area A_SP of its corresponding one among the sacrificial pads SP. As shown in FIG. 10, the horizontal area A_SP of each of the sacrificial pads SP may be larger than the horizontal area A_110 of its corresponding one among the conductive pillars 110. However, embodiments are not limited thereto. The horizontal area A_SP of a sacrificial pad SP may be smaller than the horizontal area A_110 of a conductive pillar 110.

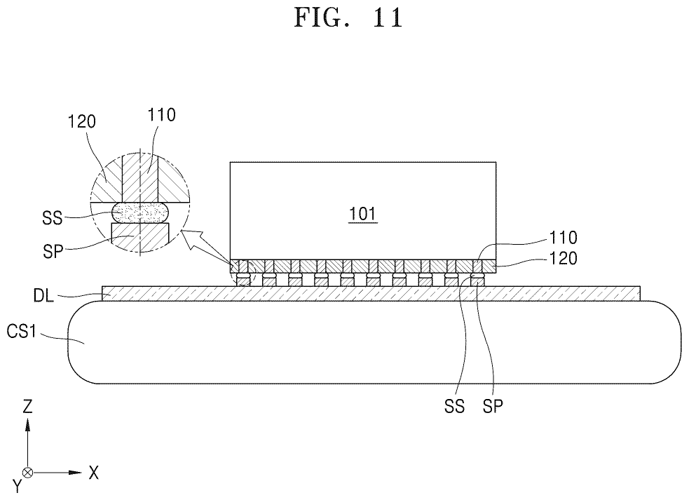

Referring to FIG. 11, the conductive pillars 110 and the sacrificial pads SP may be self-aligned with each other by performing a reflow process on the sacrificial solder bumps SS.

The sacrificial solder bumps SS may be melted by the reflow process. Due to the surface tension of the melted sacrificial solder bumps SS, the central axis of the conductive pillar 110 may be aligned with the central axis of the sacrificial pad SP with a sacrificial solder bump SS therebetween, as shown in FIG. 11.

In this regard, the conductive pillars 110 may be respectively aligned with the sacrificial pads SP without an error, and without performing an additional process. Because the protective insulating layer 120 surrounds the conductive pillars 110, the melted sacrificial solder bumps SS may be prevented from overflowing to the sidewalls of the conductive pillars 110.

In this regard, the sacrificial solder bumps SS may be in contact with the surfaces of the conductive pillars 110 and the surface of the protective insulating layer 120 but not the side surfaces of the conductive pillars 110 surrounded by the protective insulating layer 120.

In some embodiments, the protective insulating layer 120 may be apart from the adhesive insulating layer DL in the vertical direction (the Z direction). For example, the protective insulating layer 120 may be separated from the adhesive insulating layer DL by the sacrificial solder bumps SS and the sacrificial pads SP.

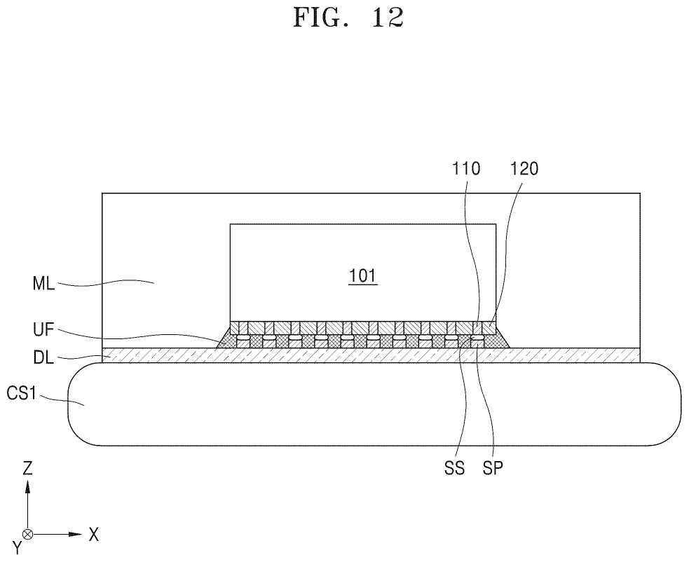

Referring to FIG. 12, an underfill process may be performed on the result structure of FIG. 11 to form an underfill layer UF between the protective insulating layer 120 and the adhesive insulating layer DL and a molding layer ML may be formed on the adhesive insulating layer DL to surround the underfill layer UF and the first semiconductor chip 101.

In detail, the underfill process may be performed to fill an empty space between the protective insulating layer 120 and the adhesive insulating layer DL. The underfill layer UF formed by the underfill process may surround a portion of the side surface of the protective insulating layer 120, the top surface of the protective insulating layer 120, the sacrificial solder bumps SS, and the sacrificial pads SP.

The molding ML may be formed on the adhesive insulating layer DL to surround the first semiconductor chip 101, a portion of the side surface of the protective insulating layer 120, which is not covered with the underfill layer UF, and the underfill layer UF. The molding layer ML may protect the first semiconductor chip 101 from external influences, such as impact and contamination.

In some embodiments, the molding layer ML may be formed without performing the underfill process. At this time, the molding layer ML may surround the sacrificial pads SP, the sacrificial solder bumps SS, the protective insulating layer 120, and the first semiconductor chip 101.

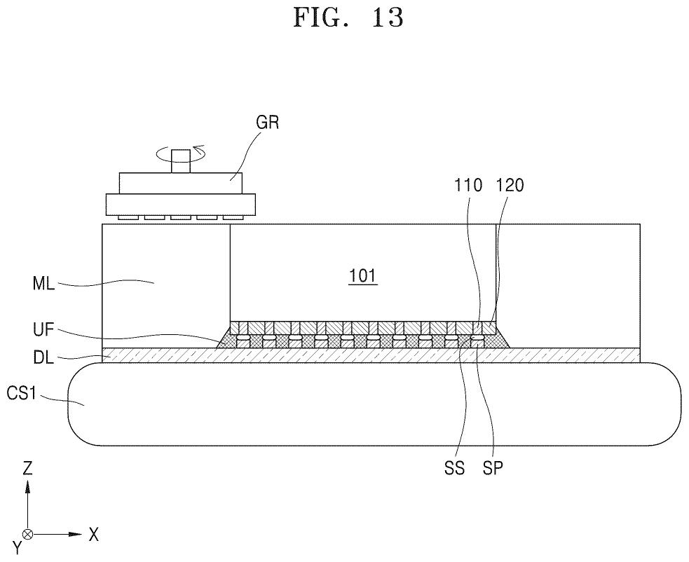

Referring to FIG. 13, the top surface of the first semiconductor chip 101 may be exposed by removing a portion of the molding layer ML.

Polishing and planarization may be performed on the molding layer ML using the grinder GR. The polishing and planarization may include CMP. The grinder GR may remove a portion of the molding layer ML. Accordingly, the top surface of the first semiconductor chip 101 may be exposed to the outside and the top surface of the molding layer ML may be coplanar with the top surface of the first semiconductor chip 101. In some embodiments, in the process of removing a portion of the molding layer ML, a portion of the first semiconductor chip 101 may also be removed.

In some embodiments, when the molding layer ML is formed to surround the side surface of the first semiconductor chip 101 in a process of forming the molding layer ML, a process of removing a portion of the molding layer ML may be omitted.

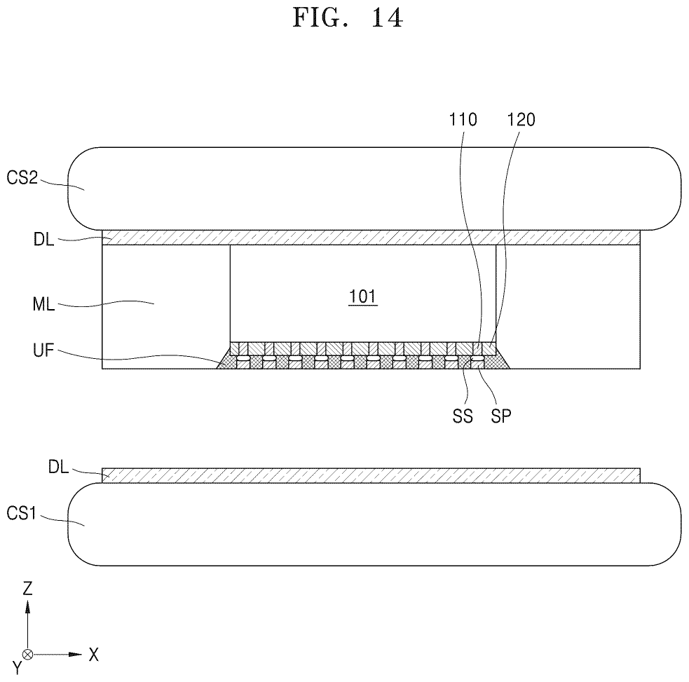

Referring to FIG. 14, a second carrier substrate CS2 may be attached to the first semiconductor chip 101 to face the first carrier substrate CS1.

The second carrier substrate CS2 may be attached to the first semiconductor chip 101 to perform subsequent processes after removing the first carrier substrate CS1. For example, the second carrier substrate CS2 may include glass, silicon, or aluminum oxide.

In some embodiments, to separate the first carrier substrate CS1 from the structure of FIG. 14, a laser beam may be radiated to the first carrier substrate CS1. The bonding force between the adhesive insulating layer DL and the first carrier substrate CS1 may be weakened by the laser irradiation. Alternatively, heat may be applied to the adhesive insulating layer DL on the first carrier substrate CS1. The bonding force between the adhesive insulating layer DL and the first carrier substrate CS1 may be weakened by the applied heat.

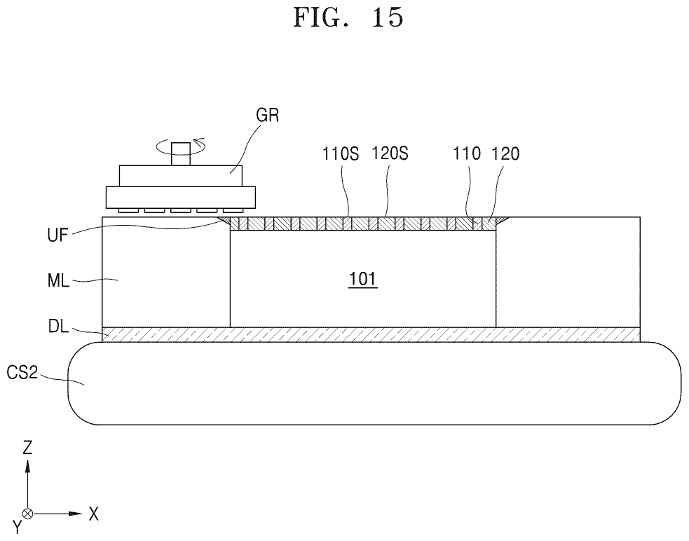

Referring to FIG. 15, the second carrier substrate CS2 may be inverted, and the conductive pillars 110 and the protective insulating layer 120 may be exposed by removing a portion of the molding layer ML, the sacrificial pads SP (see FIG. 14), and the sacrificial solder bumps SS (see FIG. 14).

Polishing and planarization may be performed using the grinder GR. The polishing and planarization may include CMP. The grinder GR may partially remove the molding layer ML and the underfill layer UF, and completely remove the sacrificial pads SP (see FIG. 14) and the sacrificial solder bumps SS (see FIG. 14). Thus, the top surface of the molding layer ML, the top surface of the underfill layer UF, respective surfaces 110S of the conductive pillars 110, and a surface 120S of the protective insulating layer 120 may form a flat surface. Accordingly, the surface 110S of the conductive pillars 110 may be coplanar with the surface 120S of the protective insulating layer 120.

In some embodiments, during the polishing and planarization by the grinder GR, the conductive pillars 110 and the protective insulating layer 120 may also be partially removed.

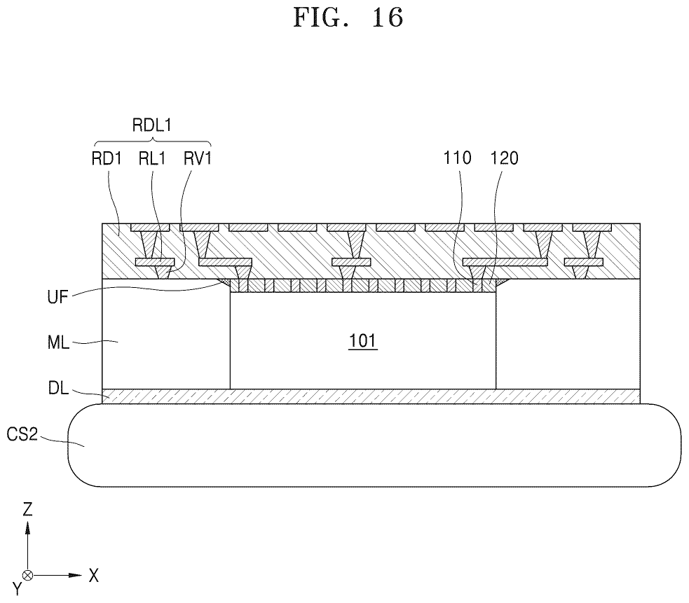

Referring to FIG. 16, a first redistribution layer RDL1 may be formed on the molding layer ML, the conductive pillars 110, and the protective insulating layer 120, which have flat surfaces due to the polishing and planarization.

The first redistribution layer RDL1 may include a first wiring line RL1, a first vertical via RV1 vertically connected to the first wiring line RL1, and a first insulating layer RD1 surrounding the first wiring line RL1 and the first vertical via RV1.

The bottom surface of the first redistribution layer RDL1 may be electrically connected to the surface of the conductive pillars 110 and may be in direct contact with the surface of the protective insulating layer 120.

According to a process of forming the first vertical via RV1, the first vertical via RV1 in the first redistribution layer RDL1 may be structured such that the horizontal area of the first vertical via RV1 decreases toward the first semiconductor chip 101.

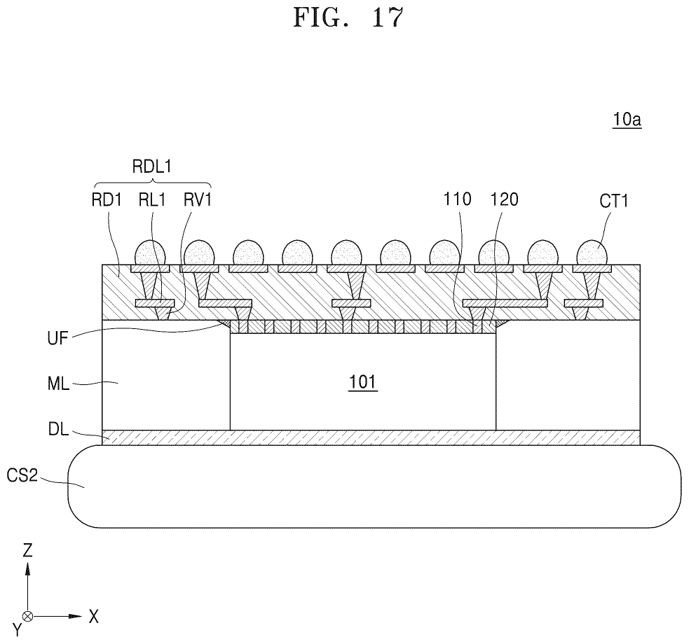

Referring to FIG. 17, an external connection terminal CT1 may be formed on the top surface of the first redistribution layer RDL1.

For example, the external connection terminal CT1 may include a solder ball, a conductive bump, conductive paste, a BGA, an LGA, a PGA, or a combination thereof. The external connection terminal CT1 may be formed on a wiring pad connected to the first wiring line RL1 of the first redistribution layer RDL1.

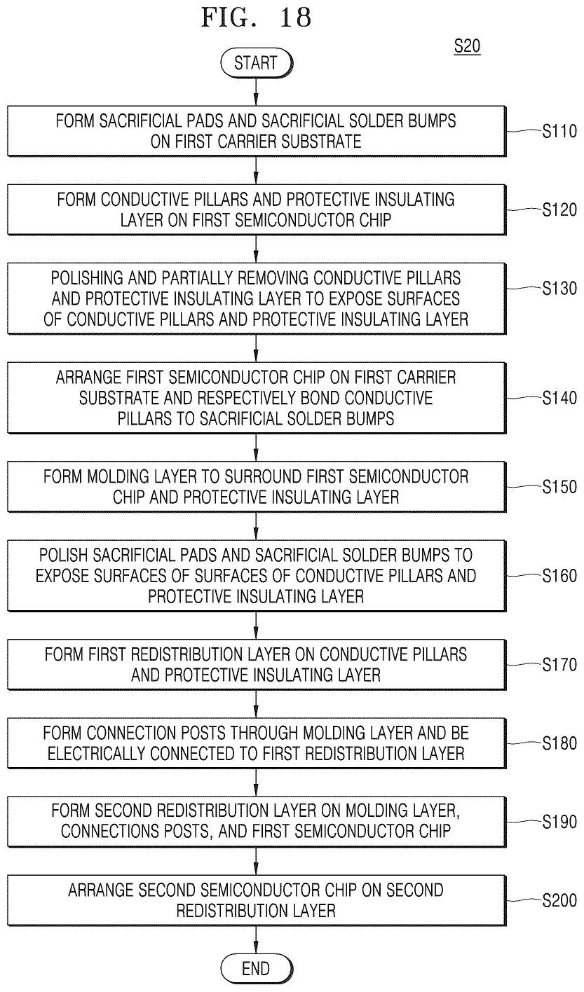

FIG. 18 is a flowchart of a method S20 of manufacturing a semiconductor package, according to an embodiment.

Referring to FIG. 18, the method S20 of manufacturing a semiconductor package may include forming a plurality of sacrificial pads and a plurality of sacrificial solder bumps on a first carrier substrate in operation S110, forming a plurality of conductive pillars and a protective insulating layer on a first semiconductor chip in operation S120, polishing and partially removing the conductive pillars and the protective insulating layer to expose the surfaces of the conductive pillars and the surface of the protective insulating layer in operation S130, arranging the first semiconductor chip on the first carrier substrate and respectively bonding the conductive pillars to the sacrificial solder bumps in operation S140, forming a molding layer to surround the first semiconductor chip and the protective insulating layer in operation S150, polishing the sacrificial pads and the sacrificial solder bumps to expose the surfaces of the conductive pillars and the surface of the protective insulating layer in operation S160, forming a first redistribution layer on the conductive pillar and the protective insulating layer in operation S170, forming a plurality of connection posts, which pass through the molding layer and are electrically connected to the first redistribution layer, in operation S180, forming a second redistribution layer on the molding layer, the connection posts, and the first semiconductor chip in operation S190, and arranging a second semiconductor chip on the second redistribution layer in operation S200.

When it is possible to modify an embodiment, the order of operations may be different from the order in which the operations are described. For example, two operations described as being performed sequentially may be substantially performed simultaneously or in a reverse order.

Briefly, the method S20 of FIG. 18 may correspond to a method of forming a package-on-package (POP) semiconductor package and may further include forming the connection posts in operation S180, forming the second redistribution layer in operation S190, and arranging the second semiconductor chip in operation S200 compared to the method S10 of FIG. 5.

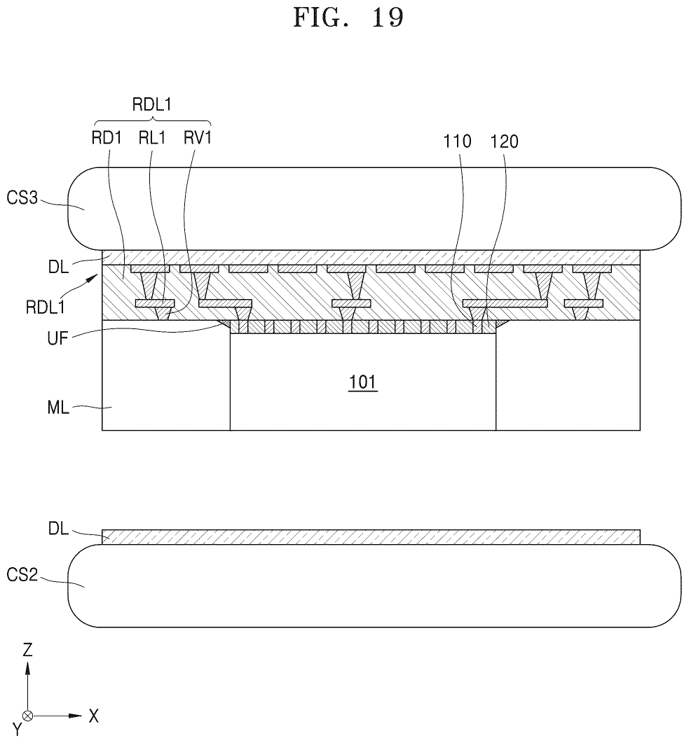

The method S20 of FIG. 18 is described in detail with reference to FIGS. 19 to 23 below.

FIGS. 19 to 23 are cross-sectional views of some sequential stages in the method S20 of manufacturing a semiconductor package, according to an embodiment. In detail, FIGS. 19 to 23 are cross-sectional views of sequential stages following the stage of FIG. 16. The stages of FIGS. 6 to 16 in the method S10 of FIG. 5 are also applied to the method S20 of FIG. 18 in substantially the same manner, and thus, redundant descriptions thereof are omitted below.

Referring to FIG. 19, a third carrier substrate CS3 may be attached to the first redistribution layer RLD1 to face the second carrier substrate CS2.

The third carrier substrate CS3 may be attached to the first redistribution layer RLD1 to perform subsequent processes after removing the second carrier substrate CS2. For example, the third carrier substrate CS3 may include glass, silicon, or aluminum oxide.

In some embodiments, to separate the second carrier substrate CS2 from the first semiconductor chip 101, a laser beam may be radiated to the second carrier substrate CS2. The bonding force between the adhesive insulating layer DL and the second carrier substrate CS2 may be weakened by the laser irradiation. Alternatively, heat may be applied to the adhesive insulating layer DL on the second carrier substrate CS2. The bonding force between the adhesive insulating layer DL and the first carrier substrate CS1 may be weakened by the applied heat.

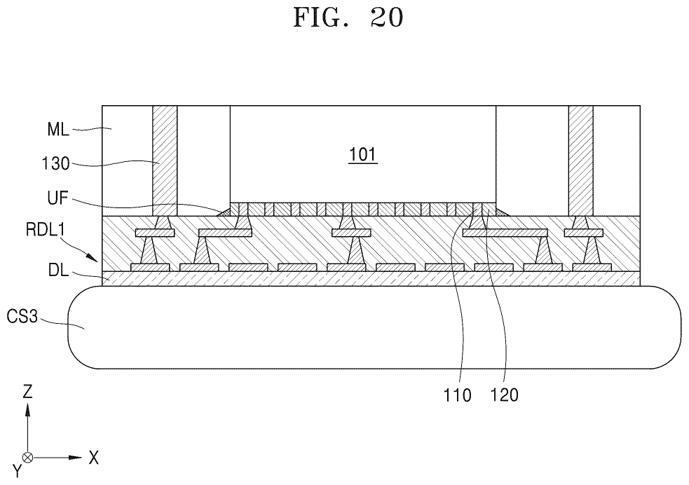

Referring to FIG. 20, a plurality of connection posts 130 may be formed through the molding layer ML.

A plurality of through holes may be formed in the molding layer ML by patterning the molding layer ML by using a photoresist process and an etching process. The through holes may be apart from the first semiconductor chip 101 in a horizontal direction. In this regard, the through holes may be formed in the molding layer ML around the first semiconductor chip 101.

The connection posts 130 respectively filling the through holes may be formed. In some embodiments, the connection posts 130 may be formed by vapor deposition or plating. Each of the connection posts 130 may be formed on the first vertical via RV1 of the first redistribution layer RLD1 and may be electrically connected to the first redistribution layer RLD1.

In some embodiments, the connection posts 130 may include, but are not limited to, metal, such as Cu, Al, W, Ti, Ta, In, Mo, Mn, Co, Sn, Ni, Mg, Re, Be, Ga, or Ru, or an alloy thereof.

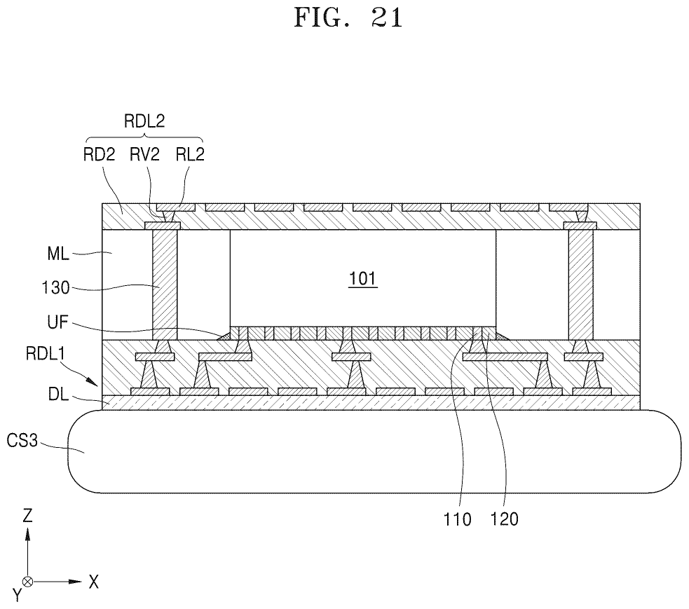

Referring to FIG. 21, a second redistribution layer RLD2 may be formed on the molding layer ML, the connection posts 130, and the first semiconductor chip 101.

The second redistribution layer RDL2 may include a second wiring line RL2, a second vertical via RV2 vertically connected to the second wiring line RL2, and a second insulating layer RD2 surrounding the second wiring line RL2 and the second vertical via RV2.

The second redistribution layer RDL2 may be electrically connected to the connection posts 130. Accordingly, the second redistribution layer RDL2 may be electrically connected to the first redistribution layer RLD1 through the connection posts 130.

According to a process of forming the second vertical via RV2, the second vertical via RV2 in the second redistribution layer RDL2 may be structured such that the horizontal area of the second vertical via RV2 decreases toward the first semiconductor chip 101.

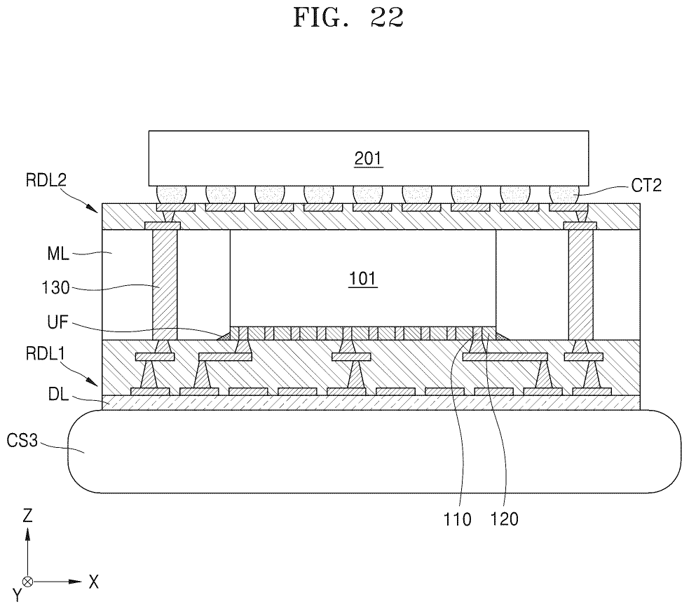

Referring to FIG. 22, a second semiconductor chip 201 may be arranged on the second redistribution layer RDL2.

The second semiconductor chip 201 may be arranged on the second redistribution layer RDL2 such that the active surface of the second semiconductor chip 201 faces the second redistribution layer RDL2. At this time, the second semiconductor chip 201 may be electrically connected to the second redistribution layer RDL2 through an internal connection terminal CT2 between the second semiconductor chip 201 and the second redistribution layer RDL2.

In this regard, the second semiconductor chip 201 may be electrically connected to the first redistribution layer RDL1 through the internal connection terminal CT2, the second redistribution layer RDL2, and the connection posts 130.

A method of arranging the second semiconductor chip 201 on the second redistribution layer RDL2 is not limited to that described above.

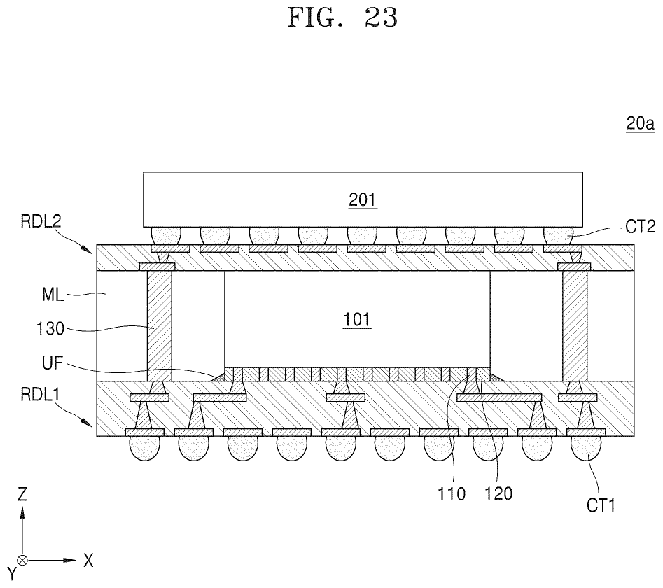

Referring to FIG. 23, the third carrier substrate CS3 may be removed and an external connection terminal CT1 may be formed on the bottom surface of the first redistribution layer RLD1.

For example, the external connection terminal CT1 may include a solder ball, a conductive bump, conductive paste, a BGA, an LGA, a PGA, or a combination thereof. The external connection terminal CT1 may be formed on a wiring pad connected to the first wiring line RL1 of the first redistribution layer RDL1.

A semiconductor package 20a may correspond to an embodiment of a semiconductor package, which further includes the underfill layer UF in FIG. 2 compared to the semiconductor package 20 of FIG. 4.

While aspects of embodiments have been particularly shown and described, it will be understood that various changes in form and details may be made therein without departing from the spirit and scope of the following claims.

1. A method of manufacturing a semiconductor package, the method comprising:
forming a plurality of sacrificial pads on a carrier substrate and a plurality of sacrificial solder bumps on the plurality of sacrificial pads, respectively;
forming a plurality of conductive pillars and a protective insulating layer on a semiconductor chip, the protective insulating layer surrounding a side surface of each of the plurality of conductive pillars;
polishing the plurality of conductive pillars and the protective insulating layer to obtain a polished surface in which a surface of each of the plurality of conductive pillars is coplanar with a surface of the protective insulating layer; and
bonding the plurality of conductive pillars to the plurality of sacrificial solder bumps, respectively.

2. The method of claim 1, wherein the protective insulating layer is provided on the plurality of conductive pillars in the forming the plurality of conductive pillars and the protective insulating layer, and
wherein the polishing the plurality of conductive pillars and the protective insulating layer comprises removing a portion of the protective insulating layer above the plurality of conductive pillars.

3. The method of claim 1, wherein, in the bonding the plurality of conductive pillars respectively to the plurality of sacrificial solder bumps, the plurality of sacrificial solder bumps contact the surface of the protective insulating layer and the surface of each of the plurality of conductive pillars but not the side surfaces of the plurality of conductive pillars.

4. The method of claim 1, wherein the bonding the plurality of conductive pillars to the plurality of sacrificial solder bumps, respectively, comprises performing a reflow process on the plurality of sacrificial solder bumps to self-align the plurality of conductive pillars and the plurality of sacrificial pads with each other due to surface tension of the plurality of sacrificial solder bumps.

5. The method of claim 1, wherein, in the bonding the plurality of conductive pillars to the plurality of sacrificial solder bumps, respectively, the protective insulating layer is spaced apart from an adhesive insulating layer on the carrier substrate in a vertical direction.

6. The method of claim 1, wherein a horizontal area of each of the plurality of conductive pillars is different from a horizontal area of a corresponding one among the plurality of sacrificial pads.

7. The method of claim 1, wherein the plurality of conductive pillars comprise a first conductive pillar and a second conductive pillar, and
wherein a horizontal area of the first conductive pillar is larger than a horizontal area of the second conductive pillar.

8. The method of claim 7, wherein the horizontal area of the first conductive pillar is about 120% to about 200% of the horizontal area of the second conductive pillar.

9. The method of claim 1, wherein a distance between respective centers of adjacent conductive pillars among the plurality of conductive pillars is about 20 μm to about 100 μm.

10. The method of claim 1, wherein the forming the plurality of conductive pillars and the protective insulating layer on the semiconductor chip comprises forming a plurality of dummy pillars on the semiconductor chip, and
wherein the protective insulating layer is offset from the side surface of each of the plurality of dummy pillars.

11. A method of manufacturing a semiconductor package, the method comprising:
forming a plurality of sacrificial pads on a first carrier substrate and a plurality of sacrificial solder bumps on the plurality of sacrificial pads, respectively;
forming a plurality of conductive pillars and a protective insulating layer on a semiconductor chip, the protective insulating layer surrounding a side surface of each of the plurality of conductive pillars;
polishing the plurality of conductive pillars and the protective insulating layer to obtain a polished surface in which a surface of each of the plurality of conductive pillars is coplanar with a surface of the protective insulating layer;
bonding the plurality of conductive pillars to the plurality of sacrificial solder bumps, respectively;
forming a molding layer on the first carrier substrate, the molding layer surrounding the protective insulating layer and the semiconductor chip;
attaching a second carrier substrate to the semiconductor chip and removing the first carrier substrate;
removing the plurality of sacrificial pads and the plurality of sacrificial solder bumps to expose the surface of each of the plurality of conductive pillars and the surface of the protective insulating layer;
forming a redistribution layer on the plurality of conductive pillars and the protective insulating layer;
forming an external connection terminal on the redistribution layer; and
removing the second carrier substrate.

12. The method of claim 11, further comprising forming an underfill layer between the semiconductor chip and the first carrier substrate, the underfill layer surrounding a portion of each of a side surface of the protective insulating layer, the plurality of sacrificial pads, and the plurality of sacrificial solder bumps.

13. The method of claim 12, wherein the forming the molding layer is performed after the forming the underfill layer, and
wherein the molding layer surrounds the underfill layer, the semiconductor chip, and another portion of the side surface of the protective insulating layer that is not covered with the underfill layer.

14. The method of claim 11, wherein, in the forming the molding layer, the molding layer surrounds each of the plurality of sacrificial pads, the plurality of sacrificial solder bumps, the protective insulating layer, and the semiconductor chip.

15. The method of claim 11, wherein the forming the molding layer comprises:
forming the molding layer to cover the semiconductor chip; and
polishing an upper portion of the molding layer to expose a top surface of the semiconductor chip.

16. The method of claim 11, wherein the removing the plurality of sacrificial pads and the plurality of sacrificial solder bumps comprises partially removing the protective insulating layer and the plurality of conductive pillars,
wherein the surface of each of the plurality of conductive pillars is coplanar with the surface of the protective insulating layer, and
wherein the side surface of each of the plurality of conductive pillars is covered with only the protective insulating layer.

17. The method of claim 11, wherein a horizontal width of a vertical via in the redistribution layer decreases toward the semiconductor chip.

18. A method of manufacturing a semiconductor package, the method comprising:
forming a plurality of sacrificial pads on a first carrier substrate and a plurality of sacrificial solder bumps on the plurality of sacrificial pads, respectively;
forming a plurality of conductive pillars and a protective insulating layer on a first semiconductor chip, the protective insulating layer surrounding a side surface of each of the plurality of conductive pillars;
polishing the plurality of conductive pillars and the protective insulating layer to obtain a polished surface in which a surface of each of the plurality of conductive pillars is coplanar with a surface of the protective insulating layer;
bonding the plurality of conductive pillars to the plurality of sacrificial solder bumps, respectively;
forming a molding layer on the first carrier substrate, the molding layer surrounding the protective insulating layer and the first semiconductor chip;
attaching a second carrier substrate to the first semiconductor chip and removing the first carrier substrate;
removing the plurality of sacrificial pads and the plurality of sacrificial solder bumps to expose the surface of each of the plurality of conductive pillars and the surface of the protective insulating layer;
forming a first redistribution layer on the plurality of conductive pillars and the protective insulating layer;
attaching a third carrier substrate to the first redistribution layer and removing the second carrier substrate;
forming a plurality of connection posts that extend through the molding layer and are electrically connected to the first redistribution layer;
forming a second redistribution layer on the molding layer, the plurality of connection posts, and the first semiconductor chip;
arranging a second semiconductor chip on the second redistribution layer; and
removing the third carrier substrate.

19. The method of claim 18, wherein a horizontal width of a first vertical via in the first redistribution layer decreases toward a bottom surface of the first semiconductor chip, and
wherein a horizontal width of a second vertical via in the second redistribution layer decreases toward a top surface of the first semiconductor chip.

20. The method of claim 18, wherein the bonding the plurality of conductive pillars respectively to the plurality of sacrificial solder bumps comprises performing a reflow process on the plurality of sacrificial solder bumps to self-align the plurality of conductive pillars and the plurality of sacrificial pads with each other due to surface tension of the plurality of sacrificial solder bumps, and
wherein the plurality of sacrificial solder bumps contact the surface of the protective insulating layer and the surface of each of the plurality of conductive pillars.

21. (canceled)
